(19) United States
(12) Patent Application Publication
(10) Pub. No.: US 2025/0106984 A1
(43) Pub. Date: Mar. 27, 2025

(54) WIRING BOARD WITH STIFFENER

(71) Applicant: KYOCCERA CORPORATION, Kyoto-shi, Kyoto (JP)

(72) Inventors: Suguru KADOWAKI, Moriyama-shi,Shiga (JP); Shohei ONIMARU, Satsumasendai-shi, Kagoshima (JP)

(73) Assignee: KYOCCERA CORPORATION, Kyoto-shi, Kyoto (JP)

(21) Appl. No.: 18/724,914

(22) PCT Filed: Dec. 23, 2022
(86) PCT No.: PCT/JP2022/047631

§ 371 Date: Jun. 27, 2024

(30) Foreign Application Priority Data
Dec. 28, 2021 (JP) 2021-214992

(51) Int. Cl. H05K 1/02; H01L 23/00; H05K 1/18

(52) U.S. Cl. CPC H05K 1/0271; H05K 1/181; H01L 24/16; H01L 2224/16225; H01L 2924/15311; H05K 2201/068; H05K 2201/10462; H05K 2201/10734

(57) ABSTRACT

A wiring board with a stiffener includes a wiring board, a mounting region located on an upper surface of the wiring board, and a stiffener located on the upper surface of the wiring board to surround the mounting region and including a first surface facing the wiring board and a second surface located opposite to the first surface. The wiring board has a first thermal expansion coefficient. The stiffener includes a first region facing the wiring board, including the first surface, and a second thermal expansion coefficient, and a second region located on a surface side opposite to the first region, including the second surface, and has a third thermal expansion coefficient. An absolute value of a difference between the first and second thermal expansion coefficients is smaller than an absolute value of a difference between the first thermal expansion coefficient and the third thermal expansion coefficient.

### TECHNICAL FIELD

The present invention relates to a wiring board with a stiffener.

### BACKGROUND OF INVENTION

A flip chip ball grid array (FC-BGA) or the like is known as an LSI package in which an LSI electronic component is mounted on a wiring board. For example, as disclosed in Patent Document 1, a stiffener is provided on a wiring board used for such an LSI package for the purpose of reinforcement, warpage correction, and the like.

### CITATION LIST

### Patent Literature

Patent Document 1: WO 2020/162417

### SUMMARY

### Solution to Problem

A wiring board with a stiffener according to the present disclosure includes a wiring board, a mounting region located on an upper surface of the wiring board, and a stiffener located on the upper surface of the wiring board to surround the mounting region and including a first surface facing the wiring board and a second surface located opposite to the first surface. The wiring board has a first thermal expansion coefficient. The stiffener includes a first region that faces the wiring board, includes the first surface, and has a second thermal expansion coefficient, and a second region that is located on a surface side opposite to the first region, includes the second surface, and has a third thermal expansion coefficient. An absolute value of a difference between the first thermal expansion coefficient and the second thermal expansion coefficient is smaller than an absolute value of a difference between the first thermal expansion coefficient and the third thermal expansion coefficient.

An electronic component mounting structure according to the present disclosure includes the above wiring board with a stiffener and an electronic component located in a mounting region.

### BRIEF DESCRIPTION OF THE DRAWINGS

FIG. 1 is an explanatory view for explaining a state in which an electronic component is mounted on a wiring board with a stiffener according to an embodiment of the present disclosure.

FIG. 2 is an enlarged explanatory view for explaining a region X illustrated in FIG. 1.

FIG. 3 is a graph showing a result of a stress simulation and a result of a warpage simulation of a corner portion of a wiring board with a stiffener including a copper stiffener (stiffener in the related art).

FIG. 4 is a graph showing a result of a stress simulation and a result of a warpage simulation of a corner portion of a wiring board with a stiffener assuming that the thermal expansion coefficient of the stiffener is 20 ppm/° C.

FIG. 5 is a graph showing a result of a stress simulation and a result of a warpage simulation of a corner portion of a wiring board with a stiffener assuming that a thermal expansion coefficient of the stiffener is 15 ppm/° C.

FIG. 6 is a graph showing a result of a stress simulation and a result of a warpage simulation of a corner portion of a wiring board with a stiffener (stiffener in the related art) made of AlSiC (SiC 40%).

FIG. 7 is a graph showing a result of a stress simulation and a result of a warpage simulation of a corner portion of a wiring board with a stiffener (stiffener in the related art) made of AlSiC (SiC 45%).

FIG. 8 is a graph showing a result of a stress simulation and a result of a warpage simulation of a corner portion of a wiring board with a stiffener (stiffener departing from the scope of the present disclosure) including copper as a bottom layer and AlSiC (SiC 40%) as a top layer.

FIG. 9 is a graph showing a result of a stress simulation and a result of a warpage simulation of a corner portion of a wiring board with a stiffener (stiffener departing from the scope of the present disclosure) including copper as a bottom layer and AlSiC (SiC 45%) as a top layer.

FIG. 10 is a graph showing a result of a stress simulation and a result of a warpage simulation of a corner portion of a wiring board with a stiffener (stiffener of the present disclosure) including copper as a top layer and AlSiC (SiC 40%) as a bottom layer.

FIG. 11 is a graph showing a result of a stress simulation and a result of a warpage simulation of a corner portion of a wiring board with a stiffener (stiffener of the present disclosure) including copper as a top layer and AlSiC (SiC 45%) as a bottom layer.

FIG. 12 is a graph showing the degree of stress relaxation for a wiring board with a stiffener (stiffener of the present disclosure) including copper as a top layer and AlSiC (SiC 40% and 45%) as bottom layers.

### DESCRIPTION OF EMBODIMENTS

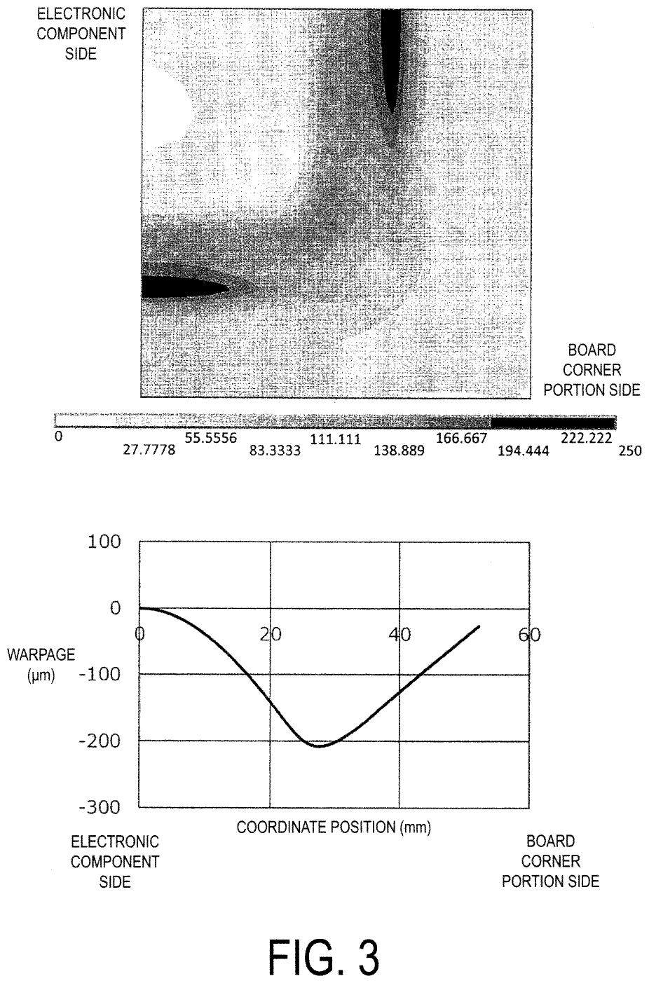

In a wiring board with a stiffener, the stiffener is generally formed of copper having a relatively large thermal expansion coefficient, and corrects the warpage of the board by using a difference in expansion and contraction between the stiffener and the board. At the time of such correction, as illustrated in FIG. 3 to be described below, stress is likely to concentrate on a region between an electronic component and the stiffener (an edge portion of the stiffener). As a result, cracks are likely to occur in a plane conductor (in particular, the plane conductor around a solder) present on a surface (opposite surface) facing this region. This leads to a demand for a wiring board in which cracks are less likely to occur even when the wiring board is repeatedly used in high-temperature and low-temperature environments.

As described above, in a wiring board according to the present disclosure, an absolute value of a difference between a first thermal expansion coefficient and a second thermal expansion coefficient is smaller than an absolute value of a difference between the first thermal expansion coefficient and a third thermal expansion coefficient. As a result, even when the wiring board according to the present disclosure is repeatedly used in high-temperature and low-temperature environments, cracks are less likely to occur.

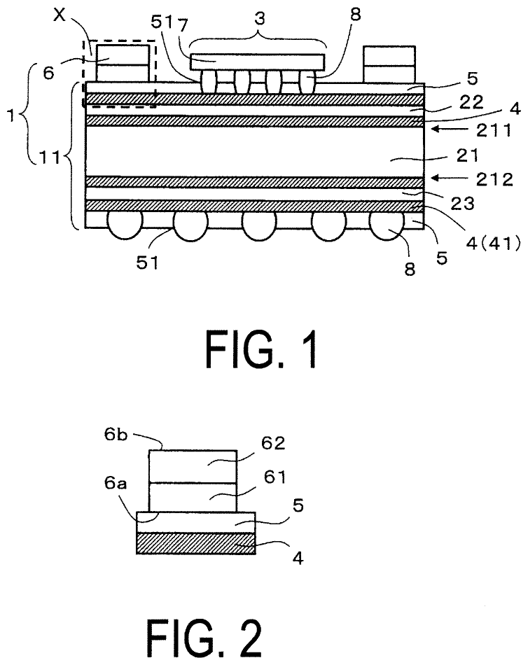

A wiring board with a stiffener according to an embodiment of the present disclosure will be described with reference to FIGS. 1 and 2. FIG. 1 is an explanatory view for explaining a state (electronic component mounting structure) in which an electronic component is mounted on a wiring board with a stiffener according to an embodiment of the present disclosure. As illustrated in FIG. 1, a wiring board 1 with a stiffener according to an embodiment includes a wiring board 11 and a stiffener 6. The wiring board 11 includes a first insulating layer 21, a second insulating layer 22, a third insulating layer 23, electrical conductor layers 4, and a solder resist 5.

The first insulating layer 21 has an upper surface 211 and a lower surface 212 located opposite to the upper surface 211. The upper surface 211 and the lower surface 212 correspond to a main surface of the first insulating layer 21. In the wiring board 11, the first insulating layer 21 corresponds to a core insulating layer.

The first insulating layer 21 is not particularly limited as long as the first insulating layer 21 is formed of a material having an insulation property. Examples of the material having an insulation property include resins such as an epoxy resin, a bismaleimide-triazine resin, a polyimide resin, and a polyphenylene ether resin. Two or more types of these resins may be mixed and used. The thickness of the first insulating layer 21 is not particularly limited and is, for example, from 400 μm to 1800 μm.

The first insulating layer 21 may include a reinforcing material. Examples of the reinforcing material include insulation fabric materials such as glass fiber, glass non-woven fabric, aramid non-woven fabric, aramid fiber, and polyester fiber. Two or more types of reinforcing materials may be used in combination. An inorganic insulation filler made of, for example, silica, barium sulfate, talc, clay, glass, calcium carbonate, or titanium oxide may be dispersed in the first insulating layer 21.

A through-hole conductor (not illustrated) is usually located in the first insulating layer 21 in order to electrically connect the upper and lower surfaces of the first insulating layer 21. The through-hole conductor is located inside a through hole passing through from the upper surface 211 to the lower surface 212 of the first insulating layer 21. The through-hole conductor is formed of, for example, metal plating such as copper plating. The through-hole conductor is connected to the electrical conductor layers 4 formed on both sides of the first insulating layer 21. The through-hole conductor may be formed only at an inner wall surface of the through hole, or the through hole may be filled with the through-hole conductor.

On the upper surface 211 of the first insulating layer 21, the electrical conductor layer 4 and an insulating layer are alternately layered. In this specification, among the insulating layers located on the upper surface 211 side, an insulating layer located at the outermost layer is defined as the second insulating layer 22. The electrical conductor layer 4 is located on the outermost surface of the wiring board 11 on the upper surface 211 side except for the solder resist 5. That is, at least two electrical conductor layers 4 and one insulating layer are layered on the upper surface 211 side, and this one insulating layer corresponds to the second insulating layer 22.

The electrical conductor layer 4 is not limited as long as the electrical conductor layer 4 is formed of a conductor such as metal. Specifically, the electrical conductor layer 4 is formed of a metal foil such as a copper foil, metal plating such as copper plating, or the like. The thickness of the electrical conductor layer 4 is not particularly limited, and is, for example, from 10 μm to 30 μm.

Like the first insulating layer 21, the insulating layer including the second insulating layer 22 is not particularly limited as long as the insulating layer is formed of a material having an insulation property. Examples of the material having an insulation property include resins such as an epoxy resin, a bismaleimide-triazine resin, a polyimide resin, and a polyphenylene ether resin. Two or more types of these resins may be mixed and used. The insulating layers including the second insulating layer 22 may be formed of the same resin, or may be formed of different resins. The insulating layer including the second insulating layer 22 and the first insulating layer 21 may be formed of the same resin, or may be formed of different resins.

An inorganic insulation filler made of, for example, silica, barium sulfate, talc, clay, glass, calcium carbonate, or titanium oxide may be dispersed in the insulating layer including the second insulating layer 22. The thickness of the insulating layers including the second insulating layer 22 is not particularly limited and is, for example, from 5 μm to 50 μm. The insulating layers including the second insulating layer 22 may have the same thickness, or may have different thicknesses.

The insulating layers including the second insulating layer 22 are formed with a via-hole conductor (not illustrated) for electrically connecting the layers. The via-hole conductor is located in a via-hole passing through upper and lower surfaces of the insulating layer including the second insulating layer 22. The via-hole conductor is formed of, for example, metal plating such as copper plating. The via-hole conductor is connected to the electrical conductor layers 4 located on both sides of the insulating layer including the second insulating layer 22. The via-hole conductor may be filled in the via-hole, or may be located only on an inner wall surface of the via-hole.

As illustrated in FIG. 1, the solder resist 5 may be located on a surface of the electrical conductor layer 4 layered on the outermost layer on the upper surface 211 side. In FIG. 1, the solder resist 5 is located only on the surface of the electrical conductor layer 4. However, the electrical conductor layer 4 is a wiring pattern, and the solder resist 5 is located on a surface of the second insulating layer 22 in a portion where the electrical conductor layer 4 is not present.

The solder resist 5 is formed of a resin, and examples of the resin include an acrylic-modified epoxy resin. An opening 51 is provided in the solder resist 5 in order to electrically connect the electrical conductor layer 4 and an electrode of an electronic component 7 via a solder 8. The opening 51 is provided in a mounting region 3, for example. A shape of the opening 51 is not limited, and is usually a circular shape in plan view, and may be a shape other than a circular shape (for example, a polygonal shape such as a quadrangular shape or an octagonal shape).

The mounting region 3 is a region for mounting the electronic component 7, and is located on the outermost surface on the upper surface 211 side. The mounting region 3 has a polygonal shape such as a quadrangular shape in plan view in accordance with the shape of the electronic component 7. Examples of the electronic component 7 mounted in the mounting region 3 include a semiconductor integrated circuit element and an optoelectronic element. A corner portion of the mounting region 3 and a corner portion of the electronic component 7 are mounted to overlap each other in plan view. The shape of the mounting region 3 is not limited, and in plan view, is not limited to a polygonal shape such as a quadrangular shape and may be a circular shape or an elliptical shape.

Also, on the lower surface 212 of the first insulating layer 21, the electrical conductor layer 4 and an insulating layer are alternately layered like the upper surface 211. In this specification, among the insulating layers located on the lower surface 212 side, an insulating layer located at the outermost layer is defined as the third insulating layer 23. Except for the solder resist 5, the electrical conductor layer 4 is located on the outermost surface of the wiring board 11 on the lower surface 212 side. That is, at least two electrical conductor layers 4 and one insulating layer are layered on the lower surface 212 side, and this one insulating layer corresponds to the third insulating layer 23.

The electrical conductor layer 4 and the insulating layer layered on the lower surface 212 are also as described for the electrical conductor layer 4 and the insulating layer layered on the upper surface 211, and detailed description thereof will be omitted. As illustrated in FIG. 1, the electrical conductor layer 4 layered on the outermost layer on the lower surface 212 side, that is, the electrical conductor layer 4 located on a surface of the third insulating layer 23 is a plane conductor layer 41.

As illustrated in FIG. 1, the solder resist 5 is located on a surface of the plane conductor layer 41. The solder resist 5 is as described above, and detailed description thereof will be omitted. In FIG. 1, the solder resist 5 is located only on the surface of the plane conductor layer 41. However, although the plane conductor layer 41 is basically a solid layer, a wiring pattern is formed in a part of the plane conductor layer 41. In a portion where the plane conductor layer 41 is not present, the solder resist 5 is located on the surface of the third insulating layer 23. The solder resist 5 located on the surface of the third insulating layer 23 and the surface of the plane conductor layer 41 is formed with the opening 51 in order to electrically connect the plane conductor layer 41 and an electrode of another wiring board (for example, a motherboard or the like) via the solder 8. The shape of the opening 51 is not limited as described above.

As illustrated in FIG. 1, in the wiring board 1 with a stiffener, the stiffener 6 is located to surround the mounting region 3. The stiffener 6 is used to improve the rigidity of the wiring board 11 and to correct the warpage of the wiring board 11. As illustrated in FIG. 2, the stiffener 6 includes a first region 61 that faces the wiring board 11, includes a first surface 6a, and has a second thermal expansion coefficient, and a second region 62 that is located on a surface side opposite to the first region 61, includes a second surface 6b, and has a third thermal expansion coefficient. The first surface 6a and the second surface 6b preferably have the same thermal expansion coefficient in each plane. The boundary between the first region 61 and the second region 62 may not be a flat surface. FIG. 2 is an enlarged explanatory view for explaining a region X illustrated in FIG. 1.

In the stiffener 6, an absolute value of a difference between a thermal expansion coefficient (defined as a first thermal expansion coefficient) of the wiring board 11 and the second thermal expansion coefficient is smaller than an absolute value of a difference between the first thermal expansion coefficient and the third thermal expansion coefficient. By using such the stiffener 6 such as described above, stress generated in a region between the electronic component 7 and the stiffener 6 (an edge portion of the stiffener 6) is reduced. As a result, cracks are less likely to occur even when the wiring board 1 is repeatedly used in high-temperature and low-temperature environments.

The stiffener 6 may have a single-layer structure, or a multilayer structure as illustrated in FIG. 2 as long as the stiffener 6 has a structure including the first region 61 and the second region 62. When the stiffener 6 has a single-layer structure, a structure in which a thermal expansion coefficient changes from the first region 61 to the second region 62 may be used.

The thermal expansion coefficient of the stiffener 6 is not limited as long as the relationship described above is satisfied, and for example, the second thermal expansion coefficient may be larger than the first thermal expansion coefficient and smaller than the third thermal expansion coefficient. That is, the thermal expansion coefficient (the third thermal expansion coefficient) of the second region 62 of the stiffener 6 may be the largest, and the thermal expansion coefficient (the first thermal expansion coefficient) of the wiring board 11 may be the smallest. When the thermal expansion coefficient satisfies such a relationship, stress generated in a region between the electronic component 7 and the stiffener 6 is further reduced while suppressing an increase in the warpage of the wiring board 1 with a stiffener.

The first thermal expansion coefficient of the wiring board 11 is, for example, from 10 ppm/° C. to 20 ppm/° C. The second thermal expansion coefficient of the first region 61 of the stiffener 6 is, for example, from 10 ppm/° C. to 25 ppm/° C. The third thermal expansion coefficient of the second region 62 of the stiffener 6 is, for example, from 15 ppm/° C. to 30 ppm/° C.

The material of the stiffener 6 is not limited as long as the material satisfies the above-described relationship between the thermal expansion coefficients. When the stiffener 6 has a single-layer structure, for example, the stiffener 6 is formed of a metal material subjected to heat treatment on only one side thereof, and is processed so that the thermal expansion coefficient changes from the second thermal expansion coefficient to the third thermal expansion coefficient from the first surface 6a to the second surface 6b.

On the other hand, when the stiffener 6 has a multilayer structure, examples of the material of the first region (first layer) 61 having the second thermal expansion coefficient include a metal-based composite material, an aluminum alloy material, and a ceramic material. Examples of the metal-based composite material include a composite material (AlSiC) in which fine silicon carbide (SiC) is dispersed in an aluminum alloy. Examples of the material of the second region (second layer) 62 having the third thermal expansion coefficient include a metal such as copper. The thickness of the first region (first layer) 61 is from 0.2 mm to 2 mm, and the thickness of the second region (second layer) 62 is from 0.2 mm to 2 mm.

The absolute value of the difference between the first thermal expansion coefficient and the second thermal expansion coefficient may be equal to or less than 10 ppm/° C., or is preferably close to 0. When the absolute value of the difference between the first thermal expansion coefficient and the second thermal expansion coefficient is equal to or less than 20 ppm/° C., stress generated in the region between the electronic component 7 and the stiffener 6 is further reduced while suppressing an increase in the warpage of the wiring board 1 with a stiffener.

The stiffener 6 is positioned on the upper surface of the wiring board 11 via, for example, a solder, an adhesive, or the like. Among these, when the stiffener 6 is positioned via the solder, the heat dissipation property of heat generated at the time of mounting the electronic component 7 or at the time of operating the electronic component mounting structure can be improved while reducing the warpage and the stress. When the stiffener 6 has a multilayer structure, the layers are bonded to each other via a solder, an adhesive, or the like, for example. Among them, when the layers are bonded via the solder, the heat dissipation property of heat generated at the time of mounting the electronic component 7 or at the time of operating the electronic component mounting structure can be improved. On the other hand, when the layers are bonded via the solder, the first region (first layer) needs to be made of a metal that is bonded to the solder. Therefore, a ceramic material is not suitable, and a material used for bonding is preferably selected as appropriate depending on the situation.

When the stiffener 6 has a multilayer structure, the stiffener 6 may have a two-layer structure including the first region (first layer) 61 and the second region (second layer) 62, or may have a layer structure of three or more layers in which at least one layer is located between the first region (first layer) 61 and the second region (second layer) 62. When the stiffener 6 has a layer structure of three or more layers, the thermal expansion coefficient of each layer is preferably decreased from the third thermal expansion coefficient to the second thermal expansion coefficient.

The second surface of the stiffener 6 may have a fin shape. Since the second surface of the stiffener 6 has a fin shape, the heat dissipation property of heat generated at the time of mounting the electronic component 7 or at the time of operating the electronic component mounting structure can be improved. The fin shape refers to, for example, a shape in which a plurality of linear projecting portions are provided on an upper surface of the stiffener 6.

The wiring board 1 with a stiffener described above is formed, for example, as follows. First, the first insulating layer 21 is prepared. Through holes are formed in the first insulating layer 21 by drilling, blasting, or laser machining. Subsequently, the electrical conductor layer 4 and the insulating layer are alternately layered on the upper surface 211 side and the lower surface 212 side of the first insulating layer 21. When the electrical conductor layer 4 is formed on a surface of the first insulating layer 21 by, for example, copper plating by a semi-additive method, a through-hole conductor may be formed in the through-hole, or the through-hole conductor may be formed in the through-hole in advance. The method for forming the electrical conductor layer 4 and the through-hole conductor is as described above, and detailed description thereof will be omitted.

The insulating layer is formed by applying a film made of a resin such as an epoxy resin, a bismaleimide-triazine resin, a polyimide resin, and a polyphenylene ether resin under vacuum and thermally curing the film. Subsequently, by performing laser machining on the insulating layer, a via-hole with the electrical conductor layer 4 as a bottom portion is formed. After the laser machining, desmear treatment for removing carbide or the like is performed to improve the adhesion strength between the via-hole and the via-hole conductor. When the electrical conductor layer 4 is formed on the surface of the insulating layer, the via-hole conductor is formed by plating metal in the via-hole.

By repeating the step of forming the electrical conductor layer 4 and the step of forming the insulating layer, a desired number of electrical conductor layers 4 and insulating layers can be formed. Among the insulating layers layered on the upper surface 211 side, an insulating layer located at the outermost layer is referred to as the second insulating layer 22, and among the insulating layers layered on the lower surface 212 side, an insulating layer located at the outermost layer is referred to as the third insulating layer 23. The electrical conductor layer 4 formed on the surface of the third insulating layer 23 is referred to as the plane conductor layer 41.

Subsequently, the surface of the second insulating layer 22, the surface of the electrical conductor layer 4 layered on the outermost layer on the upper surface 211 side, the surface of the third insulating layer 23, and the surface of the plane conductor layer 41 are covered with the solder resist 5. In the solder resist 5 covering the upper surface 211 side, the opening 51 is formed in a region serving as the mounting region 3. In the solder resist 5 covering the lower surface 212 side, the opening 51 is formed to expose a part of the plane conductor layer 41 as an electrode.

Subsequently, the stiffener 6 is formed to surround the region serving as the mounting region 3. The stiffener 6 is as described above, and detailed description thereof will be omitted.

In the manner described above, the wiring board 1 with a stiffener according to an embodiment is obtained. According to the wiring board 1 with a stiffener, in the stiffener 6, the absolute value of the difference between the thermal expansion coefficient (defined as the first thermal expansion coefficient) of the wiring board 11 and the second thermal expansion coefficient is smaller than the absolute value of the difference between the first thermal expansion coefficient and the third thermal expansion coefficient. By using the stiffener 6 such as described above, stress generated in a region between the electronic component 7 and the stiffener 6 (the edge portion of the stiffener 6) is reduced. As a result, cracks are less likely to occur even when the wiring board 1 is repeatedly used in high-temperature and low-temperature environments.

An electronic component mounting structure of the present disclosure will be described below. The electronic component mounting structure according to an embodiment includes the wiring board 1 with a stiffener and the electronic component 7 located in the mounting region 3. As described above, examples of the electronic component 7 include a semiconductor integrated circuit element and an optoelectronic element.

In the electronic component mounting structure according to an embodiment, the uppermost portion of the electronic component 7 may be located at a position lower than the second surface 6b of the stiffener 6. When the uppermost portion of the electronic components 7 is located at a position lower than the second surface 6b of the stiffener 6, the height of the electronic component mounting structure can be reduced, and damage due to contact between the electronic component 7 and the outside is easily avoided.

Subsequently, a stress simulation and a warpage measurement were performed on the wiring board with a stiffener according to the present disclosure and a wiring board with a stiffener departing from the scope of the present disclosure. These measurements were performed on one of four portions obtained by equally dividing the wiring board with a stiffener into a cross shape.

As a result of the stress simulation, a portion where stress is concentrated is darker (black). The warpage was measured diagonally from an electronic component side to a board corner side. Hereinafter, the same applies to the results of the stress simulation of the corner portion and the measurement results of the warpage.

FIG. 3 is a graph showing a result of a stress simulation and a result of a warpage simulation of a corner portion of a wiring board with a stiffener including a copper stiffener (stiffener in the related art). The copper stiffener (thickness: 2.5 mm) has a thermal expansion coefficient of about 17.6 ppm/° C., and is located on an upper surface of the wiring board with an adhesive therebetween.

From the result of the stress simulation, it can be seen that a region between the electronic component 7 and the stiffener 6 (the edge portion of the stiffener 6) is dark colored and generated stress is concentrated in this region. On the other hand, although the wiring board with a stiffener is warped, the warpage converges to around 0 at an end portion (corner portion) of the wiring board. Accordingly, although the wiring board with a stiffener can be mounted on a motherboard in terms of warpage, cracks are likely to occur when the wiring board with a stiffener is repeatedly used in high-temperature and low-temperature environments in terms of stress.

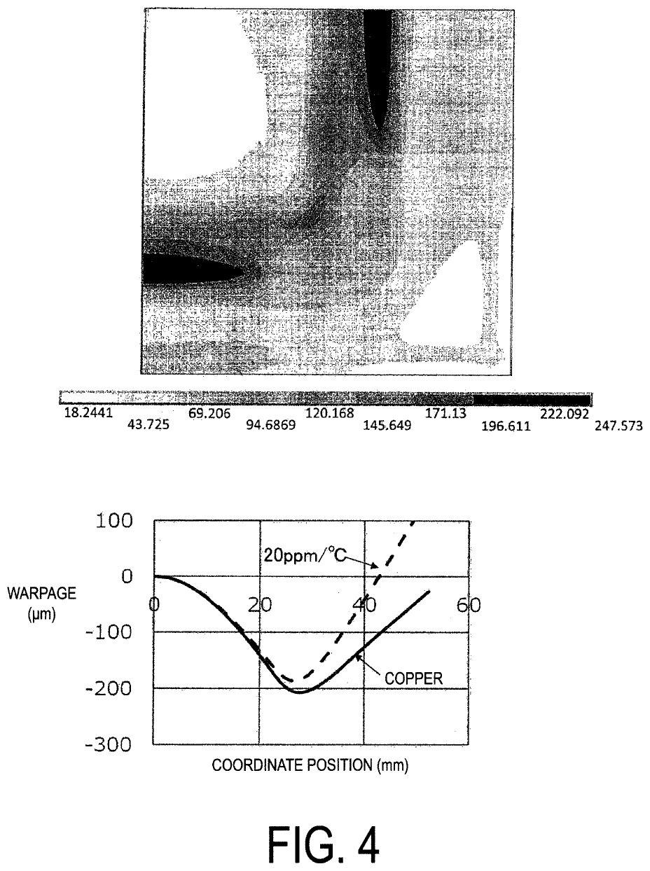

FIG. 4 is a graph showing a result of a stress simulation and a result of a warpage simulation of a corner portion of a wiring board with a stiffener (Young's modulus is set to be the same as that of copper) assuming that a thermal expansion coefficient of the stiffener is 20 ppm/° C. From the result of the stress simulation, it can be seen that the region between the electronic component 7 and the stiffener 6 (the edge portion of the stiffener 6) is darker in color than the result illustrated in FIG. 3 and generated stress is more concentrated in this region. It can also be seen that the wiring board with a stiffener is warped in the opposite direction (positive direction) at an end portion (corner portion) of the wiring board. Accordingly, the wiring board with a stiffener is not mountable on a motherboard.

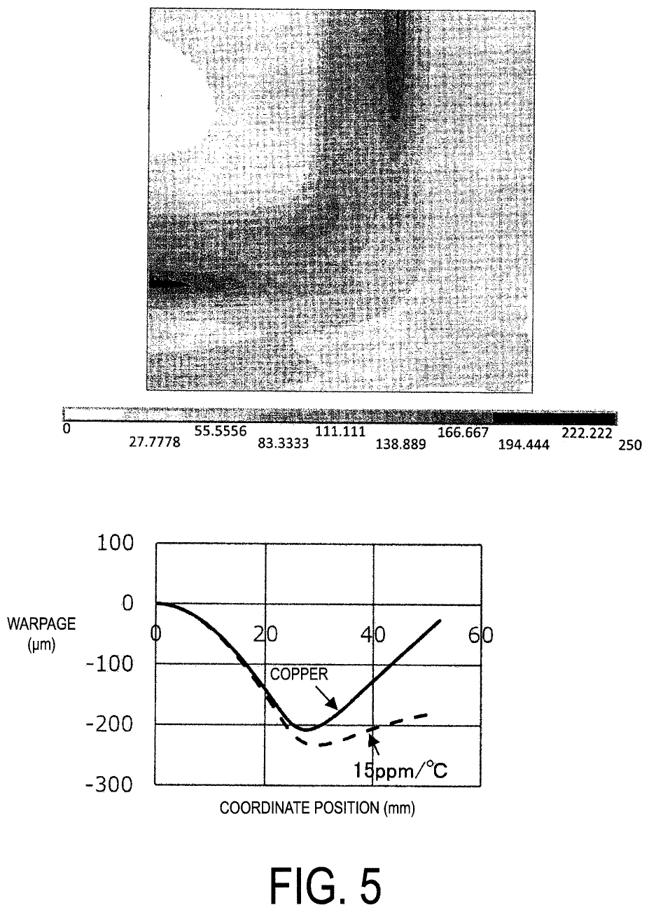

FIG. 5 is a graph showing a result of a stress simulation and a result of a warpage simulation of a corner portion of a wiring board with a stiffener (Young's modulus is set to be the same as that of copper) assuming that a thermal expansion coefficient of the stiffener is 15 ppm/° C. From the result of the stress simulation, it can be seen that the region between the electronic component 7 and the stiffener 6 (the edge portion of the stiffener 6) is thinner in color than the result illustrated in FIG. 3 and generated stress is smaller than the stress in FIG. 3. However, it can be seen that the warpage of the wiring board with a stiffener is larger than the warpage in FIG. 3 and does not converge to around 0 even at an end portion (corner portion) of the wiring board.

Accordingly, the wiring board with a stiffener is not mountable on a motherboard. As can be seen from FIGS. 4 and 5, when the thermal expansion coefficient of the stiffener is made larger than the thermal expansion coefficient of copper, the stress increases although the force for correcting the warpage is large. It can also be seen that when the thermal expansion coefficient of the stiffener is made smaller than the thermal expansion coefficient of copper, the force for correcting the warpage becomes smaller although the stress is reduced.

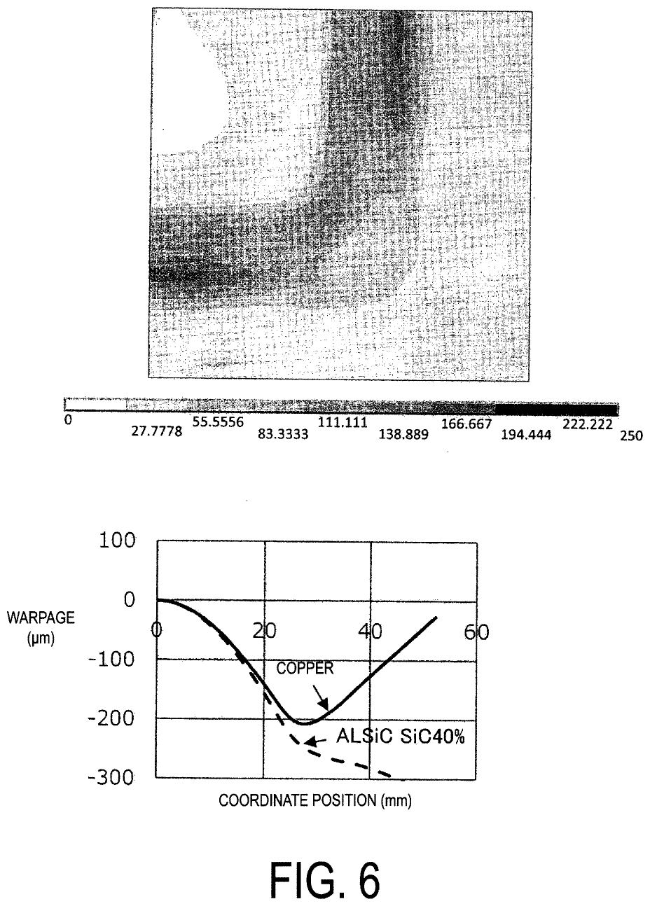

FIG. 6 is a graph showing a result of a stress simulation and a result of a warpage simulation of a corner portion of a wiring board with a stiffener (stiffener in the related art) made of AlSiC (SiC 40%). The stiffener (thickness: 2.5 mm) made of AlSiC (SiC 40%) has a thermal expansion coefficient of about 12.4 ppm/° C. and is located on an upper surface of the wiring board with an adhesive therebetween.

From the result of the stress simulation, it can be seen that the region between the electronic component 7 and the stiffener 6 (the edge portion of the stiffener 6) is thinner in color than the result illustrated in FIG. 3 and generated stress is smaller than the stress in FIG. 3. However, it can be seen that the warpage of the wiring board with a stiffener is larger than the warpage in FIG. 3 and increases toward an end portion (corner portion) of the wiring board. Accordingly, the wiring board with a stiffener is not mountable on a motherboard.

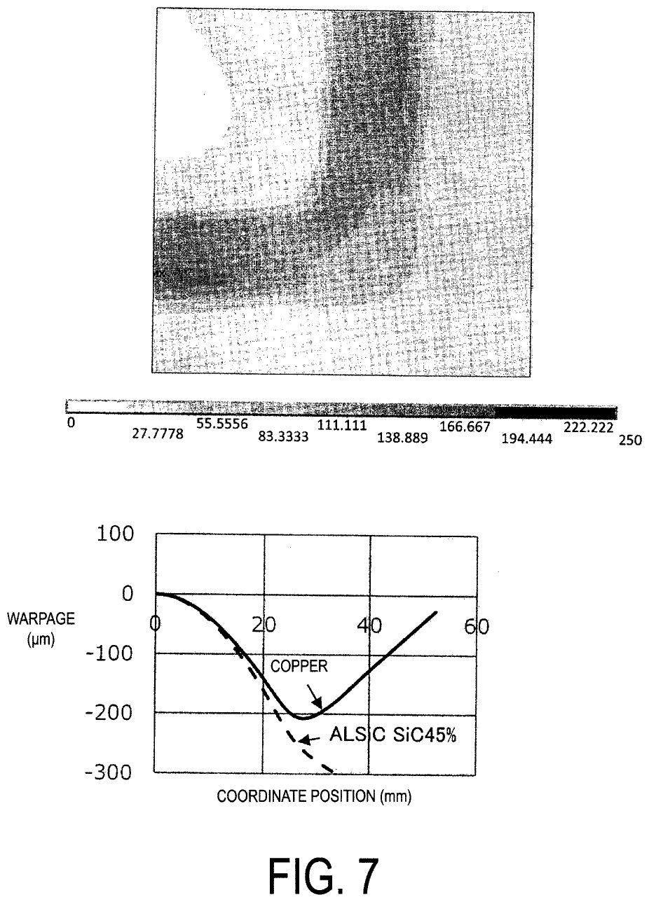

FIG. 7 is a graph showing a result of a stress simulation and a result of a warpage simulation of a corner portion of a wiring board with a stiffener (stiffener in the related art) made of AlSiC (SiC 45%). The stiffener (thickness: 2.5 mm) made of AlSiC (SiC 45%) has a thermal expansion coefficient of about 10.5 ppm/° C. and is located on an upper surface of the wiring board with a solder therebetween.

From the result of the stress simulation, it can be seen that the region between the electronic component 7 and the stiffener 6 (the edge portion of the stiffener 6) is thinner in color than the result illustrated in FIG. 3 and generated stress is smaller than the stress in FIG. 3. However, it can be seen that the warpage of the wiring board with a stiffener is large and increases toward an end portion (corner portion) of the wiring board. Accordingly, the wiring board with a stiffener is not mountable on a motherboard. As can be seen from FIGS. 6 and 7, it can be seen that as the thermal expansion coefficient of the stiffener is reduced, the force for correcting the warpage becomes smaller although the stress is reduced.

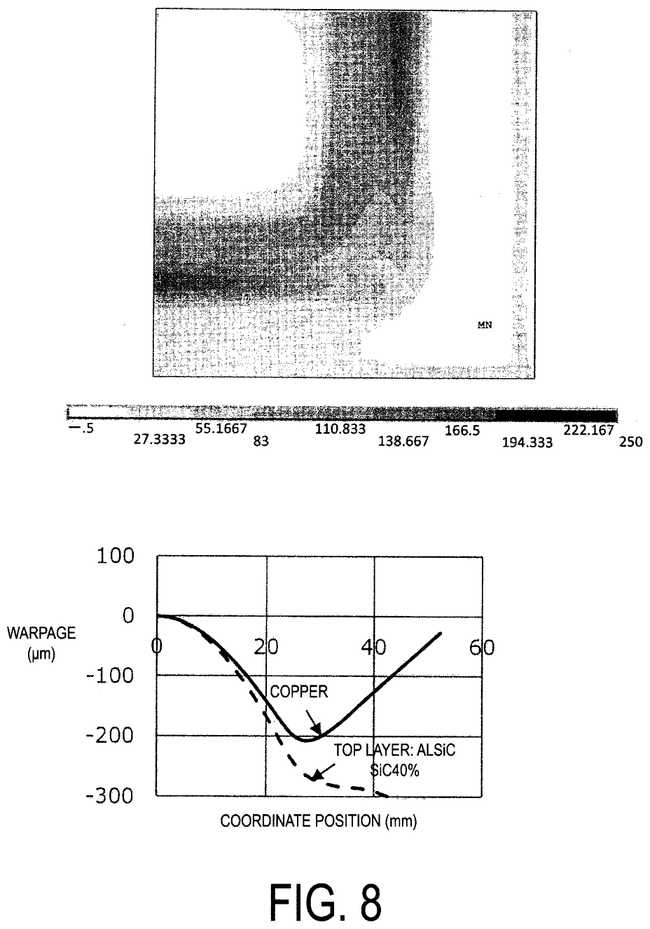

FIG. 8 is a graph showing a result of a stress simulation and a result of a warpage simulation of a corner portion of a wiring board with a stiffener (stiffener departing from the scope of the present disclosure) including copper as a bottom layer and AlSiC (SiC 40%) as a top layer. The thermal expansion coefficients of copper and AlSiC (SiC 40%) are as described above. The bottom layer and the top layer of the stiffener (thickness: 2.5 mm) are bonded to each other by an adhesive, and the stiffener is located on an upper surface of the wiring board with an adhesive therebetween.

From the result of the stress simulation, it can be seen that the region between the electronic component 7 and the stiffener 6 (the edge portion of the stiffener 6) is thinner in color than the result illustrated in FIG. 3 and generated stress is smaller than the stress in FIG. 3. However, it can be seen that the warpage of the wiring board with a stiffener is large and increases toward an end portion (corner portion) of the wiring board. Accordingly, the wiring board with a stiffener is not mountable on a motherboard.

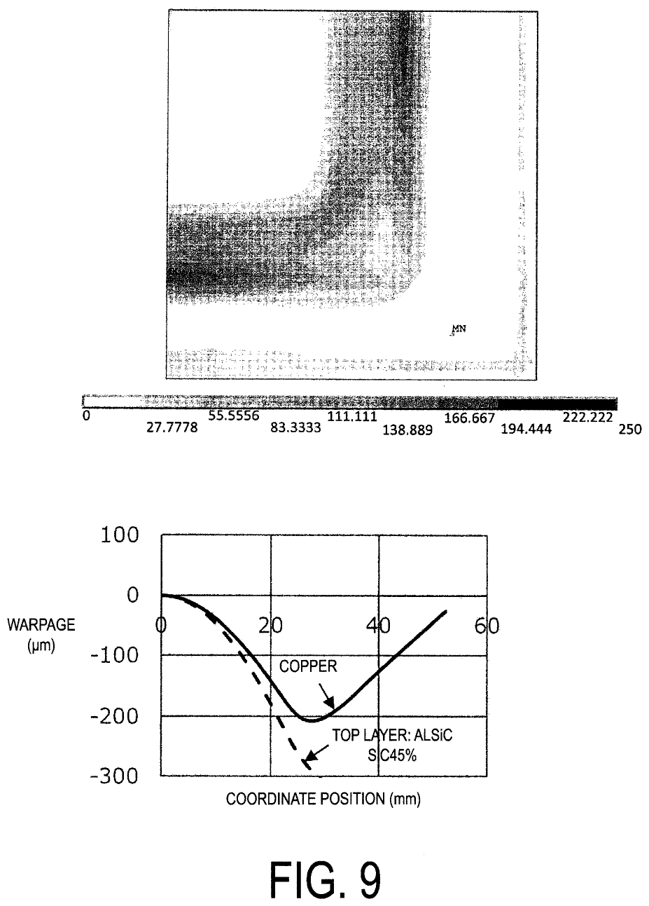

FIG. 9 is a graph showing a result of a stress simulation and a result of a warpage simulation of a corner portion of a wiring board with a stiffener (stiffener departing from the scope of the present disclosure) including copper as a bottom layer and AlSiC (SiC 45%) as a top layer. The thermal expansion coefficients of copper and AlSiC (SiC 45%) are as described above. The bottom layer and the top layer of the stiffener (thickness: 2.5 mm) are bonded to each other by an adhesive, and the stiffener is located on an upper surface of the wiring board with an adhesive therebetween.

From the result of the stress simulation, it can be seen that the region between the electronic component 7 and the stiffener 6 (the edge portion of the stiffener 6) is thinner in color than the result illustrated in FIG. 3 and generated stress is smaller than the stress in FIG. 3. However, it can be seen that the warpage of the wiring board with a stiffener is large and increases toward an end portion (corner portion) of the wiring board. Accordingly, the wiring board with a stiffener is not mountable on a motherboard. As can be seen from FIGS. 8 and 9, it can be seen that the stress is reduced but the force for correcting the warpage is small as compared with the copper-only case by adopting the two-layer structure in which copper is used as the bottom layer and the material (AlSiC) having a smaller thermal expansion coefficient than copper is used as the top layer. It can also be seen that as the thermal expansion coefficient of a material having a smaller thermal expansion coefficient than copper is made smaller, the force for correcting the warpage becomes smaller although the stress is further reduced, which is the same as the tendency in FIGS. 6 and 7.

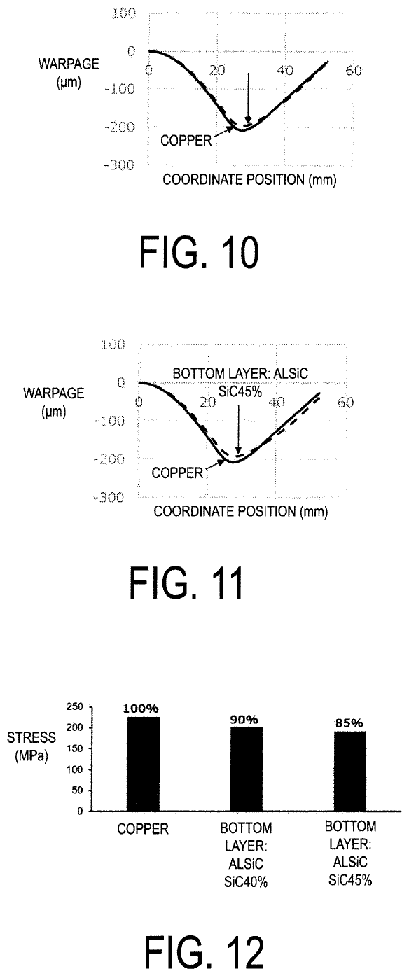

FIG. 10 is a graph showing a result of a stress simulation of a corner portion and a result of a warpage simulation of a corner portion of a wiring board with a stiffener (stiffener of the present disclosure) including AlSiC (SiC 40%) as a bottom layer and copper as a top layer. The thermal expansion coefficients of copper and AlSiC (SiC 40%) are as described above. The bottom layer and the top layer of the stiffener (thickness: 2.5 mm) are bonded to each other by an adhesive, and the stiffener is located on an upper surface of the wiring board with an adhesive therebetween.

From the result of the stress simulation, it can be seen that the region between the electronic component 7 and the stiffener 6 (the edge portion of the stiffener 6) is thinner in color than the result illustrated in FIG. 3 and generated stress is smaller than the stress in FIG. 3. Although the wiring board with a stiffener is warped, the warpage converges to around 0 at an end portion (corner portion) of the wiring board, like the wiring board with a stiffener using the copper stiffener illustrated in FIG. 3. Accordingly, in terms of warpage, the wiring board with a stiffener can be mounted on a motherboard.

FIG. 11 is a graph showing a result of a stress simulation of a corner portion and a result of a warpage simulation of a corner portion of a wiring board with a stiffener (stiffener of the present disclosure) including AlSiC (SiC 45%) as a bottom layer and copper as a top layer. The thermal expansion coefficients of copper and AlSiC (SiC 45%) are as described above. The bottom layer and the top layer of the stiffener (thickness: 2.5 mm) are bonded to each other by a solder, and the stiffener is located on an upper surface of the wiring board with a solder therebetween.

From the result of the stress simulation, it can be seen that the region between the electronic component 7 and the stiffener 6 (the edge portion of the stiffener 6) is thinner in color than the result illustrated in FIG. 3 and generated stress is smaller than the stress in FIG. 3. Although the wiring board with a stiffener is warped, the warpage converges to around 0 at an end portion (corner portion) of the wiring board, like the wiring board with a stiffener using the copper stiffener illustrated in FIG. 3. Accordingly, in terms of warpage, the wiring board with a stiffener can be mounted on a motherboard. As can be seen from FIGS. 10 and 11, it can be seen that the stress can be reduced while suppressing an increase in warpage as compared with the case of only copper by adopting the two-layer structure in which copper is used as the top layer side and the material (AlSiC) having a smaller thermal expansion coefficient than copper is used as the bottom layer.

FIG. 12 is a graph showing the degree of stress relaxation for a wiring board with a stiffener (stiffener of the present disclosure) including copper as a top layer and AlSiC (SiC 40% and 45%) as bottom layers. The graph illustrated in FIG. 12 shows relative values of the stress generated in the wiring board with a stiffener using the stiffener of the present disclosure when the stress generated in the wiring board with a stiffener using the copper stiffener illustrated in FIG. 3 is set to 100. The stress is further reduced when AlSiC (SiC 45%) having a smaller thermal expansion coefficient is used.

As illustrated in FIG. 12, it can be seen that the stress generated in the wiring board with a stiffener (stiffener of the present disclosure) including AlSiC (SiC 40%) as the bottom layer and copper as the top layer is 90% of the stress generated in the wiring board with a stiffener using the copper stiffener and the generated stress is reduced by as much as 10%.

It can be seen that the stress generated in the wiring board with a stiffener (stiffener of the present disclosure) including AlSiC (SiC 45%) as the bottom layer and copper as the top layer is 85% of the stress generated in the wiring board with a stiffener using the copper stiffener and the generated stress is reduced by as much as 15%.

### REFERENCE SIGNS

1 Wiring board with stiffener
11 Wiring board
21 First insulating layer
22 Second insulating layer
23 Third insulating layer
3 Mounting region
4 Electrical conductor layer
41 Plane conductor layer
5 Solder resist
51 Opening
6 Stiffener
61 First region (first layer)
62 Second region (second layer)
6a First surface
6b Second surface
7 Electronic component
8 Solder

1. A wiring board with a stiffener comprising:
a wiring board;
a mounting region located on an upper surface of the wiring board; and
a stiffener located on the upper surface of the wiring board to surround the mounting region and comprising a first surface facing the wiring board and a second surface located opposite to the first surface, wherein
the wiring board has a first thermal expansion coefficient,
the stiffener comprises a first region that faces the wiring board, comprises the first surface, and has a second thermal expansion coefficient, and a second region that is located on a surface side opposite to the first region, comprises the second surface, and has a third thermal expansion coefficient, and
an absolute value of a difference between the first thermal expansion coefficient and the second thermal expansion coefficient is smaller than an absolute value of a difference between the first thermal expansion coefficient and the third thermal expansion coefficient.

2. The wiring board with a stiffener according to claim 1, wherein the stiffener has a layer structure comprising at least a first layer where the first region is located and a second layer where the second region is located.

3. The wiring board with a stiffener according to claim 1, wherein
the second thermal expansion coefficient is larger than the first thermal expansion coefficient and smaller than the third thermal expansion coefficient.

4. The wiring board with a stiffener according to claim 1, wherein
the absolute value of the difference between the first thermal expansion coefficient and the second thermal expansion coefficient is equal to or less than 10 ppm/° C.

5. The wiring board with a stiffener according to claim 1, wherein
the stiffener is located on the upper surface of the wiring board with a solder therebetween.

6. The wiring board with a stiffener according to claim 2, wherein
the stiffener has a structure in which the layers are bonded to each other via a solder.

7. The wiring board with a stiffener according to claim 1, wherein
the second surface of the stiffener has a fin shape.

8. An electronic component mounting structure comprising:
the wiring board with a stiffener according to claim 1; and
an electronic component located in the mounting region.

9. The electronic component mounting structure according to claim 8, wherein
an uppermost portion of the electronic component is located at a position lower than the second surface of the stiffener.
